(19) United States
(12) Patent Application Publication
(10) Pub. No.: US 2004/0192023 A1
(43) Pub. Date: Sep. 30, 2004

(54) Methods of forming conductive patterns using barrier layers

(76) Inventors: Jong-myeong Lee, Gyeonggi-do (KR); Gil-heyun Choi, Gyeonggi-do (KR); Sang-woo Lee, Seoul (KR); Byung-hee Kim, Seoul (KR); Jung-hun Seo, Gyeonggi-do (KR)

Correspondence Address: MYERS BIGEL SIBLEY & SAJOVEC, PO BOX 37428, RALEIGH, NC, 27627, US

(21) Appl. No.: 10/813,330

(22) Filed: Mar. 30, 2004

(30) Foreign Application Priority Data
Mar. 31, 2003 (KR) 10-2003-0020165

(51) Int. Cl. H01L 21/4763; H01L 21/44

(52) U.S. Cl. 438/622; 438/643; 438/653

(57) ABSTRACT

A conductive pattern can be formed in a mold layer by removing a portion of a barrier layer outside an intaglio pattern in a mold layer to expose an upper surface of the mold layer and avoiding removing a portion of the barrier layer on the intaglio pattern. A conductive layer can be formed on the portion of the barrier layer on the intaglio pattern and on the upper surface of the mold layer. The conductive layer can be removed from the upper surface of the mold layer.

### CROSS-REFERENCE TO RELATED APPLICATION AND CLAIM FOR PRIORITY

This application is related to and claims priority from Korean Patent Application No. 2003-20165, filed on Mar. 31, 2003 in the Korean Intellectual Property Office, the disclosure of which is hereby incorporated herein by reference as if set forth in its entirety.

### FIELD OF THE INVENTION

The invention relates generally to methods of forming integrated circuit devices and, more particularly, to a methods of forming metal patterns integrated circuit devices.

### BACKGROUND

As semiconductor devices are scaled down, the width of the metal lines therein (i.e., linewidth) may also be reduced. Consequently, a ratio of the height of metal lines to the width of the metal lines may increase. This may lead to difficulty in performing a photolithographic or etching process for forming the metal lines. To overcome such a difficulty, a damascene process has been proposed. The damascene process can be used to form copper or aluminum lines where it may be otherwise difficult to perform other processes (particularly, etching processes).

A method of forming a semiconductor device using a conventional damascene process will now be described with reference to FIG. 1 and FIG. 2. Referring to FIG. 1 and FIG. 2, an interlayer dielectric 2 is formed on a substrate 1. The interlayer dielectric 2 is patterned to form a groove 3 having a line shape. A diffusion barrier layer 4 is formed on an entire surface of a substrate 1 and in the groove 3. The diffusion barrier layer 4 is made of titanium nitride and may act as a wetting layer.

An aluminum layer 5 is formed on the diffusion barrier layer 4 to fill the groove 3. The aluminum layer 5 and the diffusion barrier layer 4 are planarized (using chemical mechanical polishing (CMP)) to expose a top surface of the interlayer dielectric 2 to form a diffusion barrier pattern 4a and an aluminum line 5a which are sequentially stacked in the groove 3.

During the CMP process, remnants of the diffusion barrier layer 4 may cause a top surface of the aluminum line 5a to be scratched, which may cause defects in the device having the aluminum line 5a. For example, the scratches may cause the electromigration (EM) characteristics of the aluminum line 5a to deteriorate or the debris from the scratches may cause electrical shorts.

### BRIEF DESCRIPTION OF THE DRAWINGS

FIG. 1 and FIG. 2 are cross-sectional views illustrating a method of forming a semiconductor using a conventional damascene process.

FIG. 3 through FIG. 9 are cross-sectional views illustrating methods of forming an integrated circuit device according to some embodiments of the invention.

FIG. 10 through FIG. 14 are cross-sectional views illustrating methods of forming an integrated circuit device according to some embodiments of the invention.

FIG. 15 is a cross-sectional view illustrating methods of forming a pattern according to some embodiments of the invention.

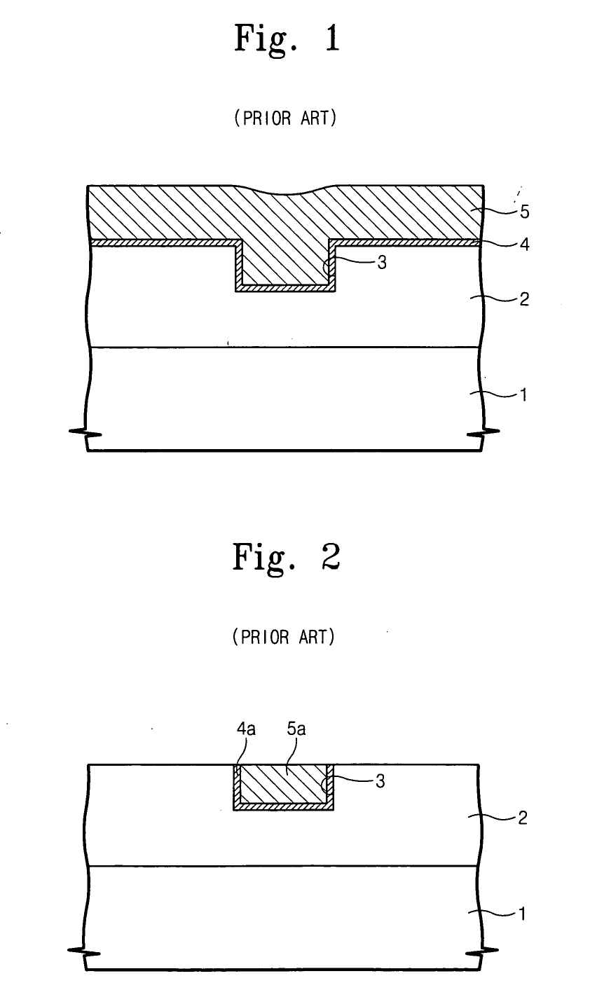

### SUMMARY

Embodiments according to the invention can provide methods of forming conductive patterns using barrier layers. Pursuant to these embodiments, conductive patterns can be formed by removing a portion of a barrier layer outside an intaglio pattern in a mold layer to expose an upper surface of the mold layer and avoiding removing a portion of the barrier layer on the intaglio pattern. A conductive layer is formed on the portion of the barrier layer on the intaglio pattern and on the upper surface of the mold layer. The conductive layer is removed from the upper surface of the mold layer.

In some embodiments according to the invention, a contact hole is formed in a first mold layer on a lower conductive pattern. A first barrier layer is formed in the contact hole and outside the contact hole on an upper surface of the first mold layer. A first flowable material is formed on the barrier layer. The first flowable material is removed to expose the upper surface of the first mold layer and to avoid removing the first flowable material from inside the contact hole. The first flowable material is removed from inside the contact hole. A first conductive layer is formed in the contact hole and on the exposed upper surface of the first mold layer. The first conductive layer is removed to expose the upper surface of the first mold layer and to avoid removing the first conductive layer from inside the contact hole. A second mold layer is formed on the first mold layer. A groove is formed in the second mold layer on the contact hole. A second barrier layer is formed in the groove and outside the groove on an upper surface of the second mold layer. A second flowable material is formed on the second barrier layer. The second flowable material is removed to expose the upper surface of the second mold layer and to avoid removing the second flowable material from inside the groove. The second flowable material is removed from inside the groove. A second conductive layer is formed in the groove and on the exposed upper surface of the second mold layer. The second conductive layer is removed to expose the upper surface of the second mold layer and to avoid removing the second conductive layer from inside the groove.

In some embodiments according to the invention, a contact hole is formed in a mold layer on a lower conductive pattern. A groove is formed on the contact hole, the groove being wider than the contact hole. A barrier layer is formed in the groove and outside the groove on an upper surface of the mold layer. A flowable material is formed on the barrier layer. The flowable material is removed to expose the upper surface of the mold layer and to avoid removing the flowable material from inside the groove. The flowable material is removed from inside the groove. A conductive layer is formed in the groove and on the exposed upper surface of the mold layer. The conductive layer is removed to expose the upper surface of the mold layer and to avoid removing the conductive layer from inside the groove.

### DESCRIPTION OF EMBODIMENTS ACCORDING TO THE INVENTION

The invention is described hereinafter with reference to the accompanying drawings, in which embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the height of layers and regions are exaggerated for clarity. It will also be understood that when a layer is referred to as being “on” another layer or substrate, it can be directly on the other layer or substrate, or intervening layers may also be present. Like numbers refer to like elements throughout.

Furthermore, relative terms, such as “lower” and “upper”, may be used herein to describe one element's relationship to another element as illustrated in the Figures. It will be understood that relative terms are intended to encompass different orientations of the device in addition to the orientation depicted in the Figures. For example, if the device in the Figures is turned over, elements described as being on the “lower” of other elements would then be oriented on “upper” of the other elements. The exemplary term “lower”, can therefore, encompass both an orientation of lower and upper, depending of the particular orientation of the figure.

It will be understood that although the terms first and second may be used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second without departing from the teachings of the present invention. Like numbers refer to like elements throughout.

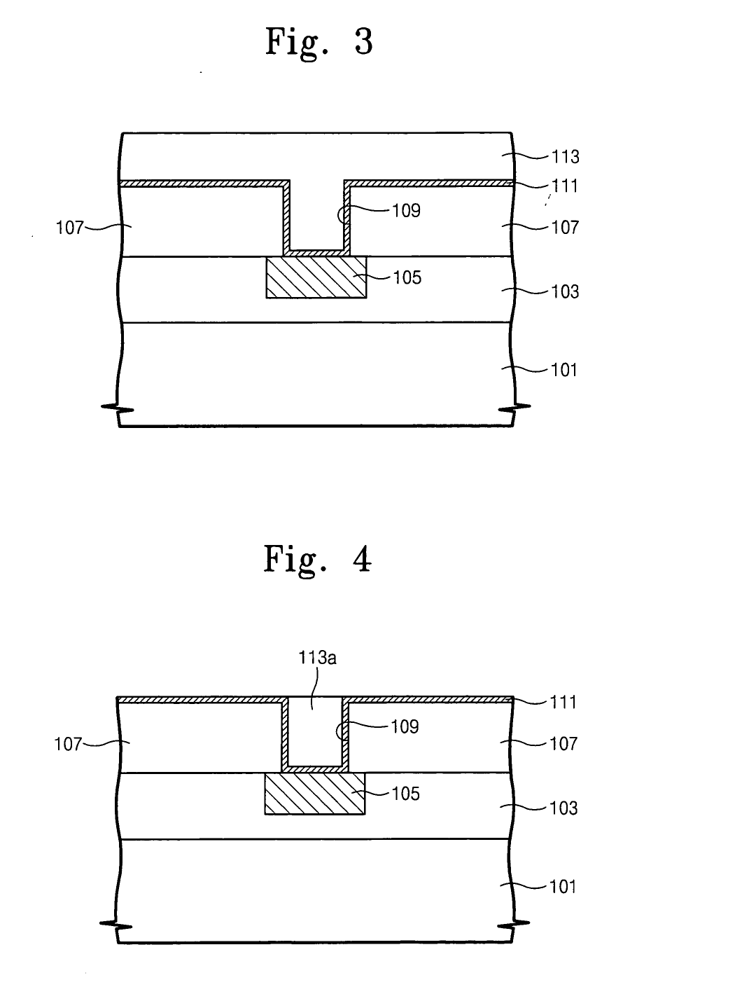

Referring to FIG. 3, a lower insulation layer 103 is formed on an integrated circuit substrate 101 (such as a semiconductor substrate). A lower conductive pattern 105 is formed in a recess in the lower insulation layer 103. The lower insulation layer 103 may be made of silicon oxide. It will be understood that the lower conductive pattern 105 may be formed on the lower insulation layer 103 outside the recess in the lower insulation layer 103. The lower conductive pattern 105 is made of a conductive material such as doped polysilicon or metal. It will be understood that the lower insulation layer 103 and the lower conductive pattern 105 may or may not be present in embodiments according to the invention.

A first mold layer 107 is formed on the surface of the substrate 101 including on the lower conductive pattern 105. The first mold layer 107 may be CVD silicon oxide (i.e., silicon oxide formed using chemical vapor deposition). The first mold layer 107 is patterned to form a contact hole 109 exposing a predetermined region of the lower conductive pattern 105. The contact hole 109 corresponds to a first “intaglio” pattern. As used herein, the term “intaglio” is defined to include the formation of a feature below the surface of another material. A first barrier layer 111 is conformally deposited on the surface of the first mold layer 107 including in the contact hole 109. Preferably, the first barrier layer 111 is a material selected from the group consisting of Ti, Ta, TiN, Ti/TiN, TaN, Ta/TaN, WN, and combinations thereof.

A first flowable material layer 113 is formed on the first barrier layer 111 to fill the contact hole 109. The first flowable material layer 113 is a material that has good flowable characteristics, such as a photoresist or SOG (spin on glass). Preferably, the first flowable material layer 113 is a material having an etch selectivity with respect to the first mold layer 107.

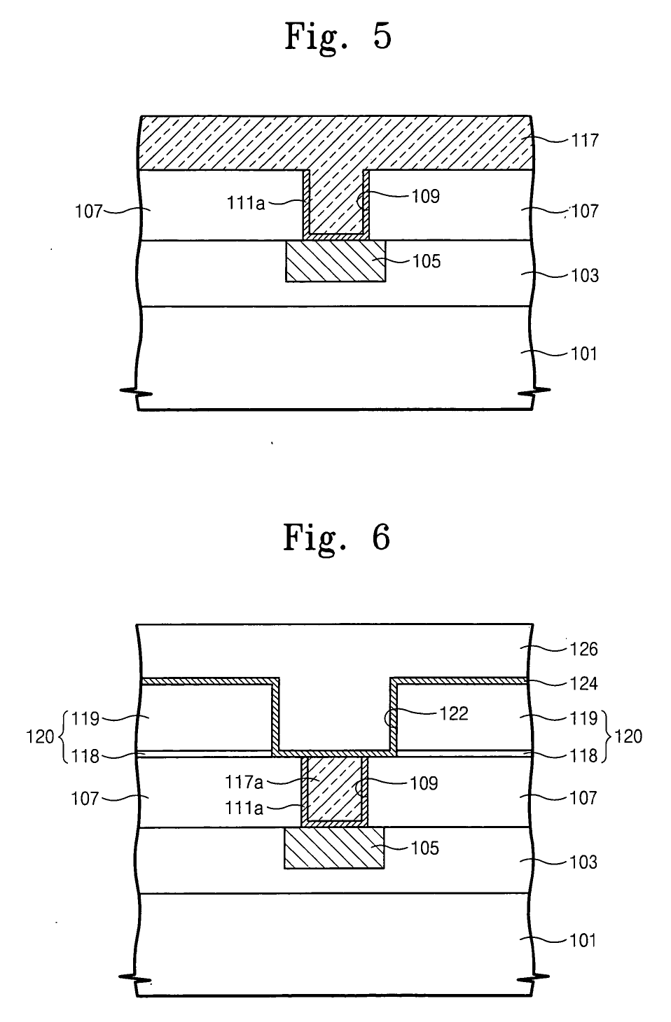

Referring to FIG. 4 and FIG. 5, the first flowable material layer 113 is anisotropically etched, until the first barrier layer 111 formed on the first mold layer 107 is exposed, to form a first flowable material pattern 113a in the contact hole 109. The anisotropic etch may employ an etch-back process.

The exposed first barrier layer 111 is planarized down to a top surface of the first mold layer 107 to form a first barrier pattern 111a in the contact hole 109. The first flowable material pattern 113a is removed from the contact hole 109 to expose the first barrier pattern 111a thereunder. Because the first flowable material pattern 113a has an etch selectivity with respect to the first mold layer 107, the first mold layer 107 may be protected while the first flowable material pattern 113a is removed. In embodiments according to the invention where the first flowable material pattern 113a is a photoresist, it may be removed using a developer or by an ashing process using an etchant such as oxygen plasma. In embodiments according to the invention where the first flowable material pattern 113a is SOG, it is preferably removed using a phosphoric acid containing solution or a fluoric acid containing solution. An etch selectivity of the phosphoric acid containing solution to CVD silicon oxide and SOG is about 1:40, and an etch selectivity of the fluoric acid containing solution to CVD silicon oxide and SOG is about 1:6.

A first metal layer 117 is formed on the surface of the first mold layer 107 including on the exposed first barrier pattern 111a to fill the contact hole 109. Preferably, in some embodiments according to the invention, the first metal layer 117 is an aluminum layer that is deposited by chemical vapor deposition (CVD) and a sputtering process. The deposited aluminum layer may be subjected to a reflow process that can be provided, for example, by annealing. The reflow process can cause atoms in the deposited aluminum layer to migrate so that the contact hole 109 is filled by the deposited aluminum layer. In some embodiments according to the invention, the first metal layer 117 is tungsten or copper.

An exemplary method of forming the aluminum layer is now described. The aluminum layer is conformally deposited on the substrate 101 including on the first barrier pattern 111a, using CVD. The CVD aluminum layer is also deposited on a sidewall of the contact hole 109. A physical vapor deposition (PVD) aluminum layer is deposited on the CVD aluminum layer by a high-throughput sputtering process. The substrate 101 including the CVD and PVD aluminum layers is subjected to a reflow process, forming an aluminum layer that fills the contact hole 109. The CVD and PVD aluminum layers may be an aluminum-alloy layer including an amount of silicon or copper atoms. Alternatively, the aluminum layer may be a single layer of CVD aluminum or PVD aluminum.

Referring to FIG. 6, the first metal layer 117 is planarized down to expose an upper surface of the first mold layer 107 to form a first metal pattern 109 in the contact hole 109. In this case, the first metal pattern 109 has a contact plug shape. The planarization process is carried out using a CMP process. Since the first barrier pattern 111 a is formed only in the contact hole 109, it is not subject to the CMP. Therefore, it is possible to reduce or avoid scratching the first metal layer 117 with remnants of the barrier layer.

An etch-stop layer 118 and an interlayer dielectric 119 are sequentially formed on the first mold layer 107 including on the first metal pattern 117a in the contact hole 109. The etch-stop layer 118 and the interlayer dielectric 119 provide a second mold layer 120. In some embodiments according to the invention, the interlayer dielectric 119 is CVD silicon oxide. The etch-stop layer 118 is an insulation material having an etch selectivity with respect to the interlayer dielectric 119. For example, the etch-stop layer 118 may be made of silicon nitride. In some embodiments according to the invention, the etch-stop layer 118 is not present.

The interlayer dielectric 119 and the etch-stop layer 118 are patterned to form a groove 122 that exposes the first metal pattern 117a. As shown in FIG. 6, the groove 122 extends across a width of the first metal pattern 117a to provide a second intaglio pattern. A second barrier layer 124 is conformally deposited on the interlayer dielectric 119 and in the groove 122. Preferably, the second barrier layer 124 is a material selected from the group consisting of Ti, Ta, TiN, Ti/TiN, TaN, Tan/TaN, WN, and combinations thereof. In some embodiments according to the invention, the second barrier layer 124 is the same material as the first barrier layer 111.

A second flowable material layer 126 is formed on the second barrier layer 124 to fill the groove 122. Preferably, the second flowable material layer 126 is a material having an etch selectivity with respect to the second mold layer 120. In some embodiments according to the invention, the second flowable material layer 126 is a photoresist material or SOG. In some embodiments according to the invention, the second flowable material layer 126 is the same material as the first flowable material layer 113.

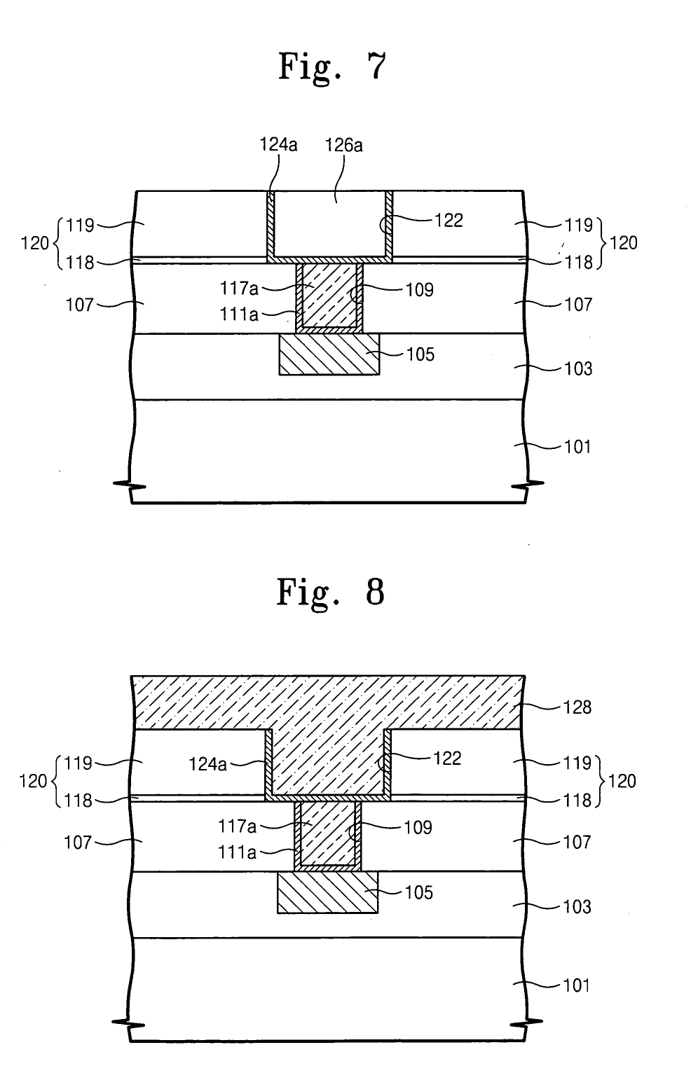

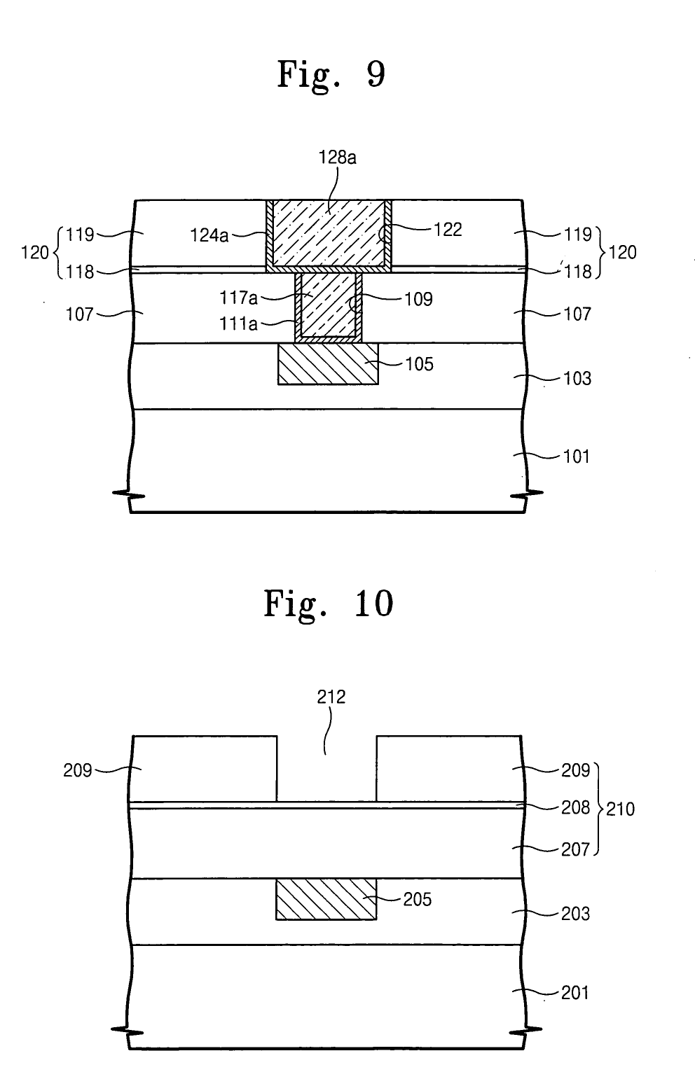

Referring to FIG. 7, FIG. 8, and FIG. 9, the second flowable material layer 126 and the second barrier layer 124 are anisotropically etched to expose an upper surface of the second mold layer 120 and to form a second barrier pattern 124a and a second flowable material pattern 126a in the groove 122. In some embodiments according to the invention, the anisotropic etch is carried out by an etch-back process. In some embodiments according to the invention, the second barrier layer 124 is completely removed from the upper surface of the second mold layer 120 by the etching.

The second flowable material pattern 126a is removed from the groove 122 to expose the second barrier 124a therein. Since the second flowable material pattern 126a has an etch selectivity with respect to the second mold layer 120, the second mold layer 120 may be protected while the second flowable material pattern 126a is removed. In embodiments according to the invention where the second flowable material pattern 126a is a photoresist, it may be removed using a developer or by an ashing process. In embodiments according to the invention where the second flowable material pattern 126a is SOG, it may be removed using a phosphoric acid containing solution or a fluoric acid containing solution.

A second metal layer 128 is formed on the second mold layer 120 and on the exposed second barrier pattern 124a to fill the groove 122. Preferably, the second material layer 128 is aluminum, which may be formed as disclosed herein with reference to the first metal layer 117. That is, an aluminum layer is preferably deposited on the second mold layer and on the second barrier pattern 124a by either one of a CVD manner or a sputtering manner. The deposited aluminum layer may be subjected to a reflow process. Alternatively, the second metal layer 128 may tungsten or copper.

The second metal layer 128 is planarized to expose an upper surface of the second mold layer 120 to form a second metal pattern 128a in the groove 122 having a metal line shape. The planarization may be achieved by a CMP process. Similar to the first barrier pattern 111a, the second barrier pattern 124a is removed from the second mold layer 120 before the planarization of the second metal layer 128. Thus, scratches to the second metal pattern 128a caused by remnants of the barrier pattern may be reduced or avoided, which may help reduce deterioration of the second metal pattern 128a.

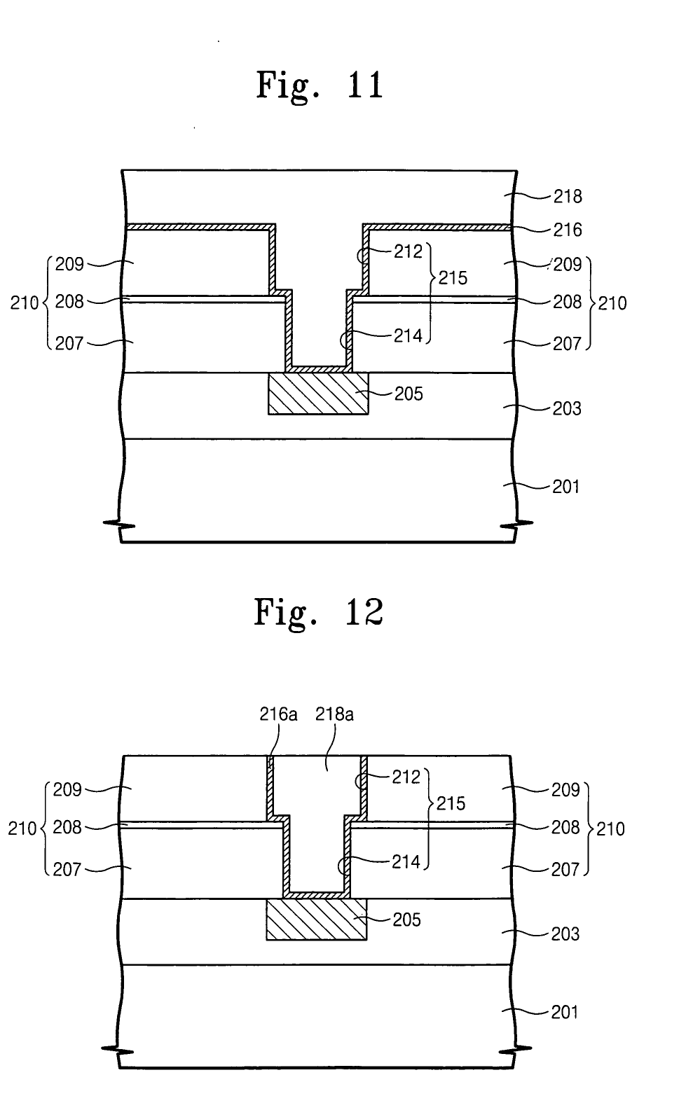

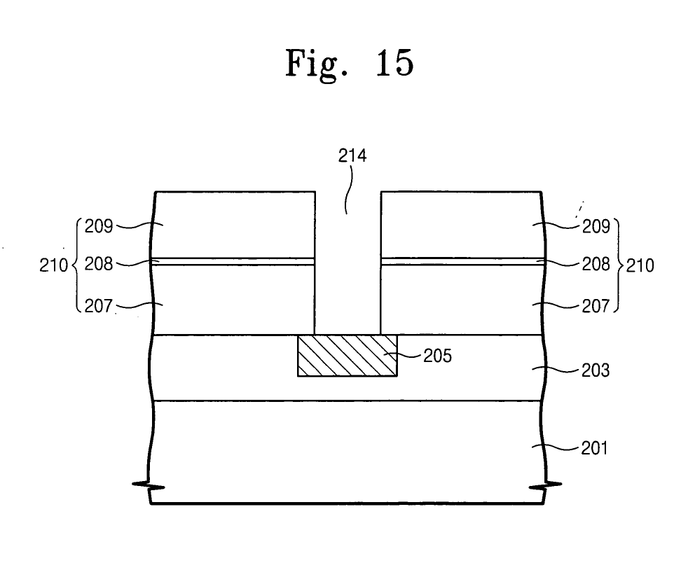

Referring to FIG. 10, FIG. 11, and FIG. 15, a lower insulation layer 203 is formed on a substrate 201. A lower conductive pattern 205 is formed in the lower insulation layer 203. Alternatively, the lower conductive pattern 205 may be formed on the lower insulation layer 203. In some embodiments according to the invention, the lower conductive pattern 205 is doped polysilicon or metal. In some embodiments according to the invention, the lower insulation layer 203 and the lower conductive pattern 205 are not present.

A first interlayer dielectric 207, an etch-stop layer 208, and a second interlayer dielectric 209 are sequentially formed on the lower insulation layer 203 and on the lower conductive pattern 205. The first interlayer dielectric 207, the etch-stop layer 208, and the second interlayer dielectric 209 define a mold layer 210. The first and second interlayer dielectrics 207 and 209 may be made of CVD silicon oxide. The etch-stop layer 208 may be made of an insulation material (e.g., silicon nitride) having an etch selectivity with respect to the second interlayer dielectric 209. In some embodiments according to the invention, the etch-stop layer 208 is absent. For example, in some embodiments according to the invention where the second interlayer dielectric 209 has an etch selectivity with respect to the first interlayer dielectric 207, the etch-stop layer 208 may be omitted.

The second interlayer dielectric 209 is patterned to form a groove 212 that exposes a predetermined region of the etch-stop layer 208. The groove 212 may be a line-shaped groove. The exposed region of the etch-stop layer 208 and the first interlayer dielectric 207 are patterned to form a contact hole 214 that exposes a predetermined region of the lower conductive pattern 205. Alternatively, in some embodiments according to the invention, the groove 212 is formed after forming the contact hole 214, as disclosed herein with reference, for example, to FIG. 15. The second interlayer dielectric 209 is patterned so that the groove 212 has a width that is greater than a width of the contact hole 214. Thus, an intaglio pattern 215 defined by the groove 212 and the contact hole 214 may be formed in the mold layer shown in FIG. 11.

A barrier layer 216 is conformally deposited on the second interlayer dielectric 209 and the intaglio pattern 215. A flowable material layer 218 is formed on the barrier layer 216 to fill the intaglio pattern 215. Preferably, the barrier layer 216 is made selected from the group consisting of Ti, Ta, TiN, Ti/TiN, TaN, Ta/TaN, WN, and combinations thereof. Preferably, the flowable material layer 218 is a material having an etch selectivity with respect to the mold layer 210. The material can be, for example, a photoresist or SOG.

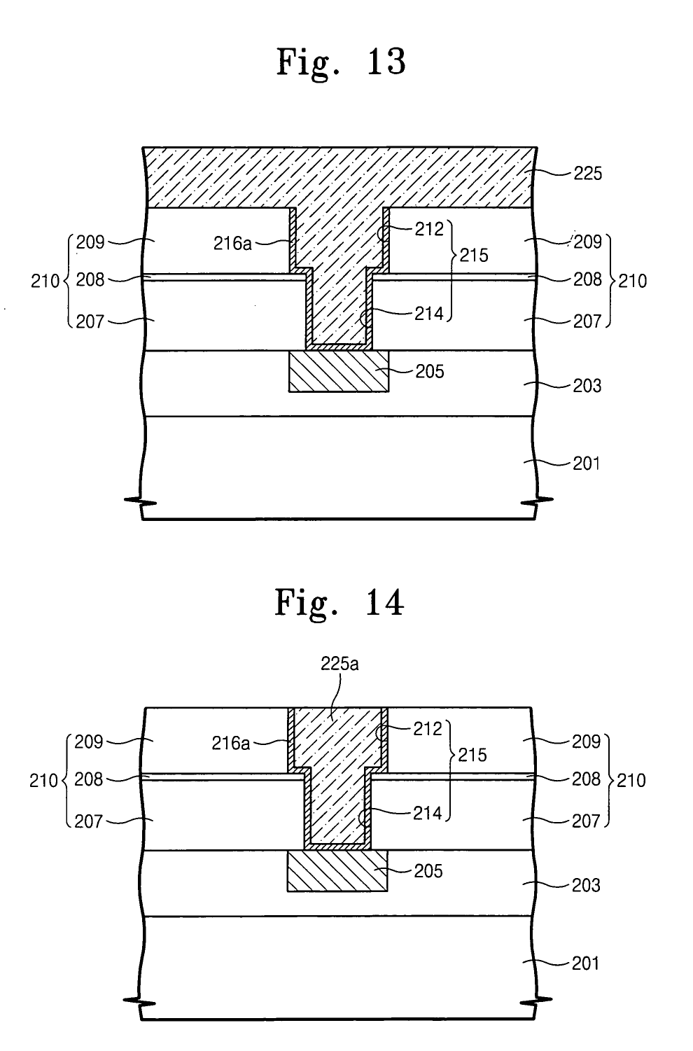

Referring to FIG. 12, FIG. 13, and FIG. 14, the flowable material layer 218 and the barrier layer 216 are planarized to expose an upper surface of the mold layer 210 to form a barrier pattern 216a and a flowable material pattern 218a in the intaglio pattern 215.

The flowable material pattern 218a is removed to expose the barrier pattern 216a. In some embodiments according to the invention where the flowable material pattern 218a is a photoresist, it is preferably removed using a developer or by an ashing process. In some embodiments according to the invention where the flowable material pattern 218a is SOG, it may be removed using a phosphoric acid containing solution or a fluoric acid containing solution.

A metal layer 225 is formed on an upper surface of the mold layer 210 and on the exposed barrier pattern 216a to fill the intaglio pattern 215. Preferably, the metal layer 225 is aluminum. A method of forming the aluminum layer may be similar to the methods of forming the first metal layer 117 disclosed in reference to FIG. 5. That is, the aluminum layer is preferably deposited by CVD or sputtering. The deposited aluminum layer may be subjected to a reflow process. Alternatively, the metal layer 225 may be tungsten or copper.

The metal layer 225 is planarized to expose an upper surface of the mold layer 210 to form a metal pattern 225a in the intaglio pattern 215. The planarization of the metal layer 225 is achieved by CMP. As described above, the barrier pattern 216 is removed from the second mold layer 210 before the planarization of the metal layer 225. Thus, scratches to the metal layer 225 caused by remnants of the barrier pattern may be reduced or avoided, which may help reduce deterioration of the metal layer 225.

While the present disclosure has been described in detail, it should be understood that various changes, substitutions, and alterations may be made hereto without departing from the spirit and the scope of the invention as defined by the appended claims.

What is claimed:

1. A method of forming a conductive pattern in a mold layer, the method comprising:
removing a portion of a barrier layer outside an intaglio pattern in a mold layer to expose an upper surface of the mold layer and avoiding removing a portion of the barrier layer on the intaglio pattern;
forming a conductive layer on the portion of the barrier layer on the intaglio pattern and on the upper surface of the mold layer; and
removing the conductive layer from the upper surface of the mold layer.

2. A method according to claim 1 wherein the barrier layer comprises a first barrier layer, the mold layer comprises a first mold layer, the intaglio pattern comprises a contact hole in the first mold layer, and the conductive layer comprises a first conductive layer, the method further comprising:
forming a groove in a second mold layer on the first mold layer, the groove being disposed above the first conductive layer in the contact hole;
forming a second barrier layer on an upper surface of the second mold layer and in the groove;
forming a flowable material on the second barrier layer;
removing a portion of the flowable material and a portion of the second barrier layer outside the groove and avoiding removing a portion of the flowable material and a portion of the second barrier layer inside the groove;
removing the portion of the flowable material from inside the groove;
forming a second conductive layer on the second barrier layer; and
removing a portion of the second conductive layer from outside groove and avoiding removing a portion of the second conductive layer inside the groove.

3. A method according to claim 1 wherein the intaglio pattern is formed by:
forming a contact hole in the mold layer; and
forming a groove in the mold layer above on the contact hole.

4. A method according to claim 3 wherein forming the conductive layer comprises forming the conductive layer in the contact hole and in the groove.

5. A method according to claim 3 wherein forming the contact hole and forming the groove comprises:
sequentially forming a first interlayer dielectric and a second interlayer dielectric on a substrate;
patterning the second interlayer dielectric to form a groove exposing a predetermined region of the first interlayer dielectric; and
patterning the exposed first interlayer dielectric to form a contact hole exposing a predetermined region of the substrate, wherein the first and second interlayer dielectric layers comprise the mold layer.

6. A method according to claim 1 wherein the barrier layer comprises at least one material selected from the group consisting of Ti, Ta, TiN, Ti/TiN, TaN, Ta/TaN, and WN.

7. A method according to claim 2 wherein the flowable material layer comprises a material having an etch selectivity with respect to the mold layer.

8. A method according to claim 7 wherein the flowable material layer comprises a photoresist.

9. A method according to claim 8 wherein the flowable material is removed using a developer.

10. A method according to claim 8 wherein the flowable material is removed by an ashing process.

11. A method according to claim 8 wherein the flowable material layer comprises SOG (spin on glass).

12. A method according to claim 11 wherein the flowable material pattern is removed using either one of a phosphoric acid containing solution and a fluoric acid containing solution.

13. A method according to claim 1 wherein the conductive layer comprises aluminum.

14. A method according to claim 13 wherein forming the conductive layer comprises forming the aluminum layer by chemical vapor deposition (CVD) or sputtering.

15. A method according to claim 14 wherein forming the aluminum layer further comprises:
performing a reflow process for a substrate including the deposited aluminum layer.

16. A method according to claim 1 wherein the conductive layer comprises one of copper and tungsten.

17. A method according to claim 1 after forming the conductive layer:
planarizing the conductive layer to expose the upper surface of the mold layer to form a metal pattern in the intaglio pattern.

18. A method according to claim 17 wherein planarizing the conductive layer comprises planarizing using a chemical mechanical polishing (CMP) process.

19. A method of forming a conductive pattern in a mold layer, the method comprising:
forming a contact hole in a first mold layer on a lower conductive pattern;
forming a first barrier layer in the contact hole and outside the contact hole on an upper surface of the first mold layer;
forming a first flowable material on the barrier layer;
removing the first flowable material to expose the upper surface of the first mold layer and to avoid removing the first flowable material from inside the contact hole;
removing the first flowable material from inside the contact hole;
forming a first conductive layer in the contact hole and on the exposed upper surface of the first mold layer;
removing the first conductive layer to expose the upper surface of the first mold layer and to avoid removing the first conductive layer from inside the contact hole;
forming a second mold layer on the first mold layer;
forming a groove in the second mold layer on the contact hole;
forming a second barrier layer in the groove and outside the groove on an upper surface of the second mold layer;
forming a second flowable material on the second barrier layer;
removing the second flowable material to expose the upper surface of the second mold layer and to avoid removing the second flowable material from inside the groove;
removing the second flowable material from inside the groove;
forming a second conductive layer in the groove and on the exposed upper surface of the second mold layer; and
removing the second conductive layer to expose the upper surface of the second mold layer and to avoid removing the second conductive layer from inside the groove.

20. A method of forming a conductive pattern in a mold layer, the method comprising:
forming a contact hole in a mold layer on a lower conductive pattern;
forming a groove on the contact hole, the groove being wider than the contact hole;
forming a barrier layer in the groove and outside the groove on an upper surface of the mold layer;
forming a flowable material on the barrier layer;
removing the flowable material to expose the upper surface of the mold layer and to avoid removing the flowable material from inside the groove;
removing the flowable material from inside the groove;
forming a conductive layer in the groove and on the exposed upper surface of the mold layer; and
removing the conductive layer to expose the upper surface of the mold layer and to avoid removing the conductive layer from inside the groove.
